(19) United States
(12) Patent Application Publication
(10) Pub. No.: US 2006/0154456 A1
(43) Pub. Date: Jul. 13, 2006

(54) Crystallized semicoductor thin film manufacturing method and its manufacturing apparatus

(75) Inventors: Yoshihiro Taniguchi, Nara-shi (JP); Hiroshi Tsunazawa, Soraku-gun (JP); Shinya Okazaki, Nara-shi (JP); Tetsuya Inui, Nara-shi (JP)

Correspondence Address: EDWARDS & ANGELL, LLP, P.O. BOX 55874, BOSTON, MA, 02205, US

(73) Assignee: SHARP KABUSHIKI KAISHA, Osaka (JP)

(21) Appl. No.: 10/542,447

(22) PCT Filed: Jan. 13, 2004
(86) PCT No.: PCT/JP04/00161

§ 371 Date: Jul. 15, 2005

(30) Foreign Application Priority Data
Jan. 15, 2003 (JP) 2003-007631

(51) Int. Cl. H01L 21/20

(52) U.S. Cl. 438/487; 438/486

(57) ABSTRACT

A fabrication method of a crystallized semiconductor thin film is such that: by performing pulse irradiation of energy beams in a minute slit shape to a semiconductor thin film (5), the semiconductor thin film (5) of an region to which the energy beams are irradiated is fused and solidified over the whole area in a thickness direction so as to be crystallized, a main beam (6) and a sub beam (7), having smaller energy per unit area than that of the main beam (6), which adjoins the main beam (6), being irradiated to the semiconductor thin film (5).

### TECHNICAL FIELD

The present invention relates to a fabrication method of a crystallized semiconductor thin film, in which a crystallized semiconductor thin film is fabricated by use of an energy beam, especially a laser light, and to a fabrication device of the crystallized semiconductor thin film.

### BACKGROUND ART

A thin film transistor, used in a display device that applies liquid crystal, electroluminescence, and/or the like, uses amorphous silicon or polycrystalline silicon as an activated layer. Out of such transistors, a thin film transistor using polycrystalline silicon as an activated layer (a crystallized semiconductor thin film) has many merits compared with a thin film transistor using amorphous silicon as an activated layer, because the former has higher electron mobility than the latter.

To put it concretely, for example, the thin film transistor using polycrystalline silicon as an activated layer not only allows formation of a switching element in a pixel part but also allows formation of (i) a driving circuit around a pixel and (ii) a part of peripheral circuits so that they are provided on a single substrate. As a result, there is no need to mount separately a driver IC or a driving circuit substrate on a display device, so that it becomes possible to provide a display device in a low price.

As for other merits, because the size of a transistor can be made smaller, a switching element formed in a pixel part becomes small, so that a high aperture ratio can be realized. As a result, it becomes possible to provide a display device with high luminance and high definition.

Incidentally, a fabrication method of the thin film transistor using polycrystalline silicon as an activated layer, namely, a fabrication method of a polycrystalline silicon thin film (a crystallized semiconductor thin film) needs a step for forming amorphous silicon on a glass substrate by use of CVD process and then poly-crystallizing the amorphous silicon.

An example of the step for poly-crystallizing (crystallizing) amorphous silicon is a high temperature anneal process or the like in which amorphous silicon is annealed at high temperature equal to or higher than 600° C. However, in a case of fabricating poly crystal silicon through the above process, there is a need to use an expensive glass substrate that can stand up to the high temperature as a substrate in which amorphous silicon is laminated, and it has prevented the price of display devices from being reduced.

But in recent years, a technology for crystallizing amorphous silicon at low temperature equal to or lower than 600° C. by use of a laser light is generally used and it becomes possible to provide in a low price a display device in which polycrystalline silicon transistor is formed on an inexpensive glass substrate.

As technologies of crystallization by a laser light, for example, a process is generally used, in which a glass substrate with an amorphous silicon thin film formed on it is heated at about 400° C. and, being scanned at fixed speed, is irradiated successively with a linear laser beam so that its length ranges from 200 to 400 mm and its width ranges from 0.2 to 1.0 mm. Through this process, it is possible to form a polycrystalline silicon thin film with an average grain size that is almost the same as a thickness of an amorphous silicon thin film. At this time, a portion of amorphous silicon to which a laser beam is irradiated does not fuse over the whole area in a thickness direction, but fuse leaving a part of an amorphous region. As a result, crystal nuclei generate everywhere over the whole area to which the laser beam is irradiated, and crystals grow toward a surface layer of the silicon thin film, so that crystal grains with random directions are formed.

But in order to obtain a more efficient display device, it is necessary to enlarge a crystal grain size of polycrystalline silicon and to control directions of growing crystals, and a lot of researches and developments have been made so as to obtain substantially the same efficiency as that of single crystal silicon.

To put it concretely, for example, Patent Document 1 discloses a technology for enlarging crystals.

Out of these technologies, especially, Patent Document 1 discloses a technology referred to as super lateral growth. A process disclosed in the Patent Document 1 is a process in which a pulse laser whose width is minute is irradiated to a silicon thin film so that the silicon thin film is fused and solidified over the whole area in a thickness direction, and crystallized.

FIG. 9 explains a process of crystallization by super lateral growth. In FIG. 9(a), for example, when a laser light whose width is minute so as to range from 2 to 3 μm is irradiated to a semiconductor thin film and a region 71 of the semiconductor thin film is fused over the whole area in a thickness direction, needle-like crystals grow in a lateral direction 72, namely, in a horizontal direction, from boundaries of regions that are not fused, and crystals that grow from both sides meet with one another at the central portion of the fused region and the growth is completed. Crystal growth in a horizontal direction as shown in FIG. 9(a) is referred to as lateral growth. Further, it is described that, as shown in FIG. 9(b) and FIG. 9(c), when a laser pulse is irradiated successively so as to overlap a part of a needle-like crystal formed by the previous laser irradiation, a needle-like crystal in a longer size grows based on an already grown crystal, and long crystals having the same direction of crystal growth can be obtained. A process in which larger crystals are grown based on crystals that have made lateral growth, as shown in FIG. 9(b) and FIG. 9(c), is referred to as super lateral growth.

Further, Patent Document 2 discloses a configuration in which a second pulse beam is irradiated to a semiconductor thin film so that a first pulse beam includes the second pulse beam.

Further, an example of a process of crystallization different from super lateral growth is a technology disclosed in Patent Document 3.

(Patent Document 1)

Publication of Patent No. 3204986 (Tokkyo 3204986) (registered date; Jun. 29, 2001)

(Patent Document 2)

Japanese Examined Patent Publication No. 79861/1991 (Tokukouhei 03-79861) (published date; Dec. 20, 1991)

(Patent Document 3)

Japanese Examined Patent Publication No. 20254/1992 (Tokukouhei 04-20254) (published date; Apr. 2, 1992)

(Non-Patent Document 1)

(The Japan Society of Applied Physics, Division of Science and Technology of Crystals, 112th workshop text P. 19˜25)

However, there is a problem that in the above conventional technologies, it is hard to extend a length of a crystal in a lateral growth direction or, even if it is possible to extend a length of a crystal in a lateral growth direction, it is very inefficient. The problem of the Patent Document 1 is fully explained below.

In the process disclosed in the Patent Document 1, a length of a crystal grown by single pulse irradiation is different according to process conditions and to a thickness of a semiconductor thin film, and it is known that: when an excimer laser whose wavelength is 308 nm is irradiated with temperature of a substrate being 300° C., a length of a crystal ranges from 1 to 1.2 μm at most (for example, see Non-patent Document 1).

However, in the process disclosed in the Patent Document 1, in order to form a long needle-like crystal shown in FIG. 9(c), it is necessary to repeat irradiation of a pulse laser in a feeding pitch ranging from about ½ to ⅓ length of a crystal grown by single pulse of laser irradiation (the length is referred to as “lateral growth length” hereinafter), namely, in a very minute feeding pitch ranging from about 0.3 to 0.6 μm. As a result, there is a problem that it takes much time to crystallize all over a substrate used in a display device, and efficiency of fabrication is very low.

Further, in the process disclosed in the Patent Document 2, the first pulse beam is irradiated so as to include the second pulse beam. The first pulse beam is irradiated to pre-heat a substrate so that heating by a heater that becomes stress between the substrate and a semiconductor thin film is removed, so that a complex device having two beam irradiating means is needed to carry out the process disclosed in the Patent Document 2.

Further, because a length of a channel of a thin film transistor is now over several μm, it is necessary to make successive growth more than several times so as to obtain crystals without any grain boundary in the moving direction of carriers. However, if single pulse of laser irradiation can grow a needle-like crystal of more than several μm in a length and can form a channel there, it becomes possible to form a thin film transistor with high mobility of carriers and excellent characteristics.

For the above reason, the technologies for super lateral growth need to further increase a length of a crystal in a lateral growth direction.

The present invention was made in view of foregoing conventional problems, and its object is to provide a fabrication method of a crystallized semiconductor thin film for further increasing the distance in a lateral growth direction, thereby efficiently fabricating a poly-crystallized semiconductor thin film of high quality, and to provide a fabrication device of the crystallized semiconductor thin film.

### DISCLOSURE OF INVENTION

In order to solve the above problem, the method according to the present invention for fabricating a crystallized semiconductor thin film includes the step of irradiating a main energy beam and a sub energy beam, whose energy per unit area is smaller than that of the main energy beam and lower than an energy threshold at which a semiconductor thin film fuses, to the semiconductor thin film formed on a substrate, so as to fuse the semiconductor thin film over a whole area in a thickness direction and crystallize the semiconductor thin film, wherein the sub energy beam is irradiated so as to adjoin the main energy beam.

With the arrangement, the sub energy beam is irradiated so as to adjoin the main energy beam. Generally, a semiconductor thin film fused by pulse irradiation of the main energy beam is crystallized from circumference. At this time, in the present invention, the sub energy beam whose energy per unit area is smaller than that of the main energy beam is irradiated to the circumference of this fused semiconductor thin film so as to adjoin the main energy beam. Further, the energy per unit area of the sub energy beam is set lower than an energy threshold at which a semiconductor thin film fuses. Namely, the circumference of the region fused by irradiation of the main energy beam is kept warm by irradiation of the sub energy beam. As a result, the fused semiconductor thin film is cooled down at a slower speed than usual. Namely, in crystallization, the fused semiconductor thin film is crystallized gradually. As a result, the size of a crystal of the crystallized semiconductor thin film can be made larger than usual. Note that the main energy beam can fuse a semiconductor thin film. Namely, energy per unit area of the main energy beam is set higher than an energy threshold at which a semiconductor thin film fuses. Namely, with the arrangement, it is possible to control speed of crystallization (solidification) of the fused semiconductor thin film, in addition to precisely control a fused region of the semiconductor thin film.

Therefore, it is possible to change spatial temperature distribution of energy that is given to the semiconductor thin film. Further, the change of temperature in time and space in solidification (crystallization) is gradual, so that it is possible to increase the length (lateral growth length) of a needle-like crystal formed through a lateral growth process (a crystal made of a material constituting the semiconductor thin film).

Further, by irradiating the sub beam so that the sub beam adjoins the main beam, it is possible to fabricate a crystallized semiconductor thin film in shorter time than, for example, an arrangement in which plural pulse lasers different from each other in terms of energy are irradiated plural times to the same region and a semiconductor thin film is crystallized. As a result, efficiency in fabrication of a crystallized semiconductor thin film becomes higher than usual.

In order to solve the above problem, the fabrication device according to the present invention for fabricating a crystallized semiconductor thin film includes energy beam irradiating means for performing pulse irradiation so that a main energy beam and a sub energy beam, whose energy per unit area is smaller than that of the main energy beam and lower than an energy threshold at which a semiconductor thin film fuses, are irradiated to a semiconductor thin film formed on a substrate, wherein the energy beam irradiating means irradiates the sub energy beam so that the sub energy beam adjoins the main energy beam.

With the arrangement, the energy beam irradiating means irradiate the sub energy beam so that the sub beam energy adjoins the main energy beam. This allows the sub beam to be irradiated to the semiconductor thin film so as to adjoin the main beam, thereby providing a fabrication device for fabricating a crystallized semiconductor thin film having crystals whose lateral growth length is large.

In order to solve the above problem, the fabrication device according to the present invention for fabricating a crystallized semiconductor thin film includes: a first beam irradiating section for irradiating a main energy beam; a first mask for forming a pattern of the main energy beam irradiated by the first beam irradiating section; a second beam irradiating section for irradiating a sub energy beam whose energy per unit area is smaller than that of the main energy beam and lower than an energy threshold at which a crystallized semiconductor thin film fuses; a second mask for forming a pattern of the sub energy beam irradiated by the second beam irradiating section; and an imaging lens for imaging patterns, respectively formed by the first mask and the second mask, on a semiconductor thin film, wherein the first mask and the second mask form patterns by which the sub energy beam is irradiated to the semiconductor thin film so as to adjoin the main energy beam.

With the arrangement, the sub energy beam is irradiated so as to adjoin the main energy beam by using two energy beam irradiating means. This allows the sub beam to be irradiated to the semiconductor thin film so as to adjoin the main beam, thereby providing a fabrication device for fabricating a crystallized semiconductor thin film whose crystals have a large lateral growth length. Further, by using two energy beam irradiating means, it is possible to form easily, for example, energy beams different from each other in terms of a wavelength.

For a fuller understanding of other purposes, characteristics and good points of the present invention, reference should be made below. Further, for a fuller understanding of advantages of the present invention, reference should be made to the below explanation with reference to drawings.

### BRIEF DESCRIPTION OF DRAWINGS

FIG. 1 is a lateral view illustrating a process for irradiating an energy beam when a crystallized semiconductor thin film of the present invention is fabricated.

FIG. 2 is a frontal view showing a structure of an outline of a fabrication device of a crystallized semiconductor thin film based on an embodiment of the present invention.

FIG. 3 is a frontal view showing a shape of a pattern formed on a mask used in a fabrication device according to the embodiment of the present invention for fabricating a crystallized semiconductor thin film.

FIG. 4 is a graph illustrating MTF (modulation transfer function) of an imaging lens used in the fabrication device of the present invention for fabricating the crystallized semiconductor thin film.

FIG. 5 is a graph showing a temperature profile of the semiconductor thin film of the embodiment of the present invention. FIG. 5(a) is a graph illustrating a condition in 25 ns after irradiation of a laser light has been started. FIG. 5(b) is a graph illustrating a condition in 60 ns after irradiation of a laser light has been started. FIG. 5(c) is a graph illustrating a condition in 70 ns after irradiation of a laser light has been started. FIG. 5(d) is a graph illustrating a condition in 100 ns after irradiation of a laser light has been started.

FIG. 6 is a frontal view showing a structure of a fabrication device according to another embodiment of the present invention for fabricating a crystallized semiconductor thin film.

FIG. 7 is a frontal view showing shapes of patterns formed on masks used in the fabrication device according to another embodiment of the present invention for fabricating the crystallized semiconductor thin film. FIG. 7(a) shows a pattern for forming a main beam and FIG. 7(b) shows a pattern for forming a sub beam.

FIG. 8 is a graph illustrating a change of time in output of a pulse laser in another embodiment of the present invention.

FIG. 9 is a frontal view showing crystal growth by general super lateral growth.

### BEST MODE FOR CARRYING OUT THE INVENTION

### First Embodiment

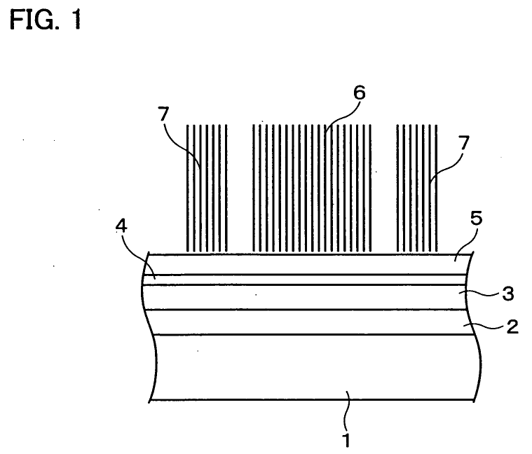

An embodiment of the present invention is explained below with reference to FIG. 1 through FIG. 5. First, a substrate including a semiconductor thin film used in a method of the present embodiment for fabricating a crystallized semiconductor thin film is explained.

The substrate including the semiconductor thin film used in the present embodiment is, as shown in FIG. 1, a substrate in which a heat-resistant thin film 2, a high heat conductive insulator film (a thermal conductive insulator film) 3, a buffer film 4, and a semiconductor thin film 5 are laminated successively on and above an insulating substrate 1.

The insulating substrate 1 can be made of glass, silica or the like, but it is preferable to use glass because glass is inexpensive and a substrate with a large region can be easily made of glass. In the present embodiment, a glass substrate of 0.7 mm in thickness is used.

The heat-resistant film 2 is formed mainly to prevent the semiconductor thin film 5, which is fused in crystallization, from having a thermal influence on the insulating substrate 1. In the present embodiment, silicon oxide of 100 nm in thickness, formed through CVD (Chemical Vapor Deposition) process, is used as the heat-resistant film 2.

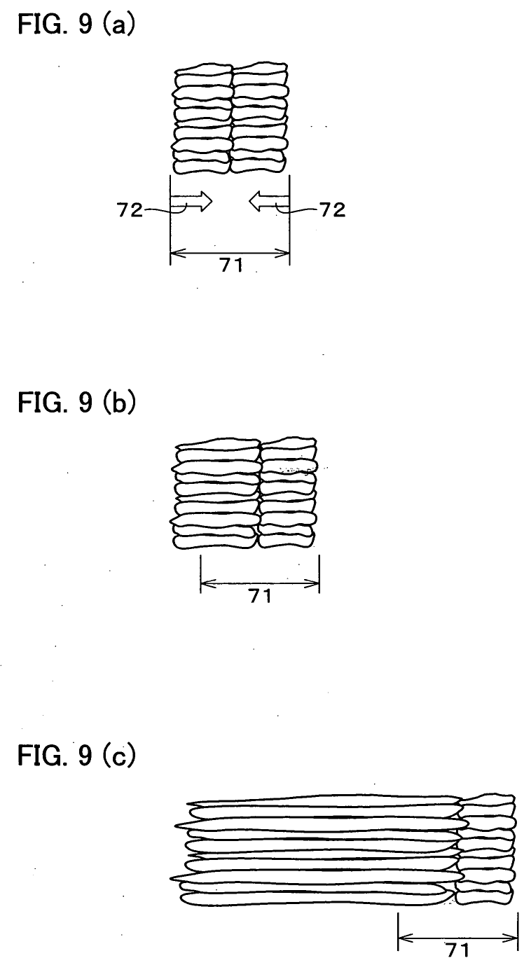

The high heat conductive insulator film 3 is used to promote crystal growth (lateral growth) in a horizontal direction 72 (see FIG. 9) by letting heat loose in a horizontal direction. Namely, the high heat conductive insulator film 3 is used to make crystals grow larger by setting the direction of crystallization. Further, it is more preferable to set a thickness of the high heat conductive insulator film 3 to be within a range of 10 to 50 nm. As for a fabrication process of the high heat conductive insulator film 3, lamination by, for example, vapor deposition, ion plating, sputtering or the like is preferable. In the present embodiment, the high heat conductive insulator film 3 is an aluminum nitride of 20 nm in thickness formed by sputtering. The high heat conductive insulator film 3 may be installed according to necessity.

As for materials constituting the high heat conductive insulator film 3, concretely, at least one material selected from, for example, aluminum nitride, silicon nitride, aluminum oxide, magnesium oxide, and cerium oxide can be used suitably.

By forming the high heat conductive insulator film 3, an inflow of heat from (i) an edge of a region having received an energy beam to (ii) a region not having received the energy beam is promoted, thereby obtaining crystals whose lateral growth length is larger than usual.

The buffer layer 4 may be formed according to necessity, so as to prevent diffusion of impurities from lower layers such as the high heat conductive insulator film 3 or the heat-resistant thin film 2, and to prevent reaction (for example, alloying) between the semiconductor thin film 5 and the high heat conductive insulator film 3 in crystallization. In the present embodiment, silicon oxide of 20 nm in thickness, made through CVD process, is used.

The semiconductor thin film 5 may be made of amorphous or crystallized semiconductor material so as to be in a range of 30 to 200 nm in thickness. In the present embodiment, amorphous silicon of 50 nm in thickness, made through CVD process, is used as the semiconductor thin film 5. Further, by poly-crystallizing the semiconductor thin film 5, it is possible to obtain a crystallized semiconductor thin film that is finally used as a product.

The following description explains a method for poly-crystallizing the semiconductor thin film 5 by irradiating a laser light to a substrate including the semiconductor thin film 5, namely, a method according to the present embodiment for fabricating a crystallized semiconductor thin film. The method according to the present embodiment for fabricating a crystallized semiconductor thin film is such that: by performing pulse irradiation so that a main energy beam (hereinafter, referred to as a main beam) and a sub energy beam (hereinafter, referred to as a sub beam), whose energy per unit area is smaller than that of the main beam and lower than an energy threshold at which a semiconductor thin film fuses, are irradiated to the semiconductor thin film formed on a substrate so that the semiconductor thin film is fused over a whole area in a thickness direction and then crystallized, the sub beam being irradiated so as to adjoin the main beam.

As shown in FIG. 1, in the present embodiment, (i) the main beam 6 for fusing, solidifying, and re-crystallizing the semiconductor thin film 5 and (ii) the sub beam 7 adjoining the main beam 6 so as to raise the temperature of the semiconductor thin film 5 are irradiated to the semiconductor thin film 5, thereby fabricating the crystallized semiconductor thin film whose crystals (grain size of crystals) are larger than usual. First, the following explains a device to form (irradiate) the beams (the main beam 6 and the sub beam 7), namely, a fabrication device according to the present embodiment for fabricating a crystallized semiconductor thin film.

The fabrication device according to the present embodiment for fabricating a crystallized semiconductor thin film includes energy beam irradiating means for performing pulse irradiation so that the main beam 6 and the sub beam 7, whose energy per unit area is smaller than that of the main beam 6 and lower than an energy threshold at which a semiconductor thin film fuses, are irradiated to a semiconductor thin film formed on a substrate, the energy beam irradiating means irradiating the sub beam 7 so that the sub beam 7 adjoins the main beam 6.

To put it more detailed, the fabrication device includes: energy beam irradiating means for performing pulse irradiation so that the main beam 6 and the sub beam 7, whose energy per unit area is smaller than that of the main beam 6 and lower than an energy threshold at which a semiconductor thin film fuses, are irradiated to the semiconductor thin film formed on the substrate; masks for forming patterns of the main beam 6 and the sub beam 7 that are irradiated to the semiconductor thin film; and an imaging lens for imaging on the semiconductor thin film the main beam 6 and the sub beam 7 that penetrate the masks, the masks being provided so that the pattern of the sub beam 7 adjoins the pattern of the main beam 6. Note that the “performing pulse irradiation” means to irradiate a pulse energy beam (for example, pulse laser).

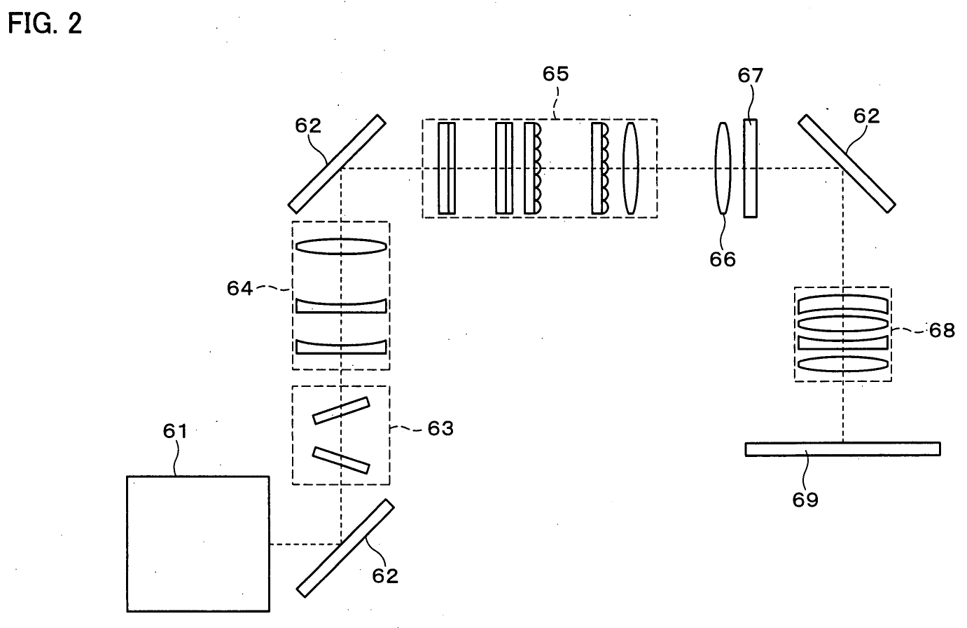

As shown in FIG. 2, the fabrication device according to the present embodiment for fabricating a crystallized semiconductor thin film includes a laser oscillator 61, a variable attenuator 63, a beam formation element 64, a mask surface uniformly illuminating element 65, a field lens 66, a mask 67, and an imaging lens 68. Note that the following explains an arrangement in which an energy beam is a laser light. Further, in the present embodiment, energy beam irradiating means include the laser oscillator 61, the variable attenuator 63, the beam formation element 64, the mask surface uniformly illuminating element 65, the field lens 66, the mask 67 and the imaging lens 68.

The laser oscillator 61 irradiates a pulse laser light (energy beam). Energy per unit area of the laser light irradiated by the laser oscillator 61 is not particularly limited so long as it can fuse the semiconductor thin film 5 (for example, amorphous silicon). Further, as for the laser oscillator 61 that can irradiate a laser light having the energy, a light source having an ultraviolet wavelength is preferable, such as an eximer laser or a variety of a solid-state laser represented by YAG laser. In the present embodiment, an eximer laser of 308 nm in wavelength is used as the laser oscillator 61.

The variable attenuator 63 has a function to adjust energy density (energy per unit area) of a laser light that reaches a substrate surface.

The beam formation element 64 and the mask surface uniformly illuminating element 65 have a function of forming a laser light irradiated by the laser oscillator 61 into a suitable size and then illuminating a mask surface uniformly. This function is, for example, as follows; by using a cylindrical lens array and a condenser lens, a laser light with Gaussian type intensity distribution (energy distribution) is divided, overlapped on the mask surface, and illuminated, thereby realizing mask illumination with uniform intensity distribution.

The field lens 66 has a function to launch the main beam 6 and the sub beam 7, having penetrated the mask 67, vertically to an imaging surface of the imaging lens 68.

The mask 67 divides a laser light irradiated to the mask 67 into the main beam 6 and the sub beam 7 and has them penetrate it. Namely, patterns formed on the mask 67 allow the main beam 6 and the sub beam 7 to be formed. The patterns formed on the mask 67 are explained later.

Further, the main beam 6 and the sub beam 7 that have penetrated the mask 67 are imaged on a substrate 69 (a semiconductor thin film), including the semiconductor thin film 5, by the imaging lens 68 at a predetermined magnification. The predetermined magnification varies according to a magnification of the imaging lens 68. In the present embodiment, a magnification of the imaging lens is ¼.

Further, a mirror 62 is used to reflect a laser light, but there is no limitation in an arrangement and the number of mirrors, and it can be arranged suitably according to optical design and mechanical design of the device.

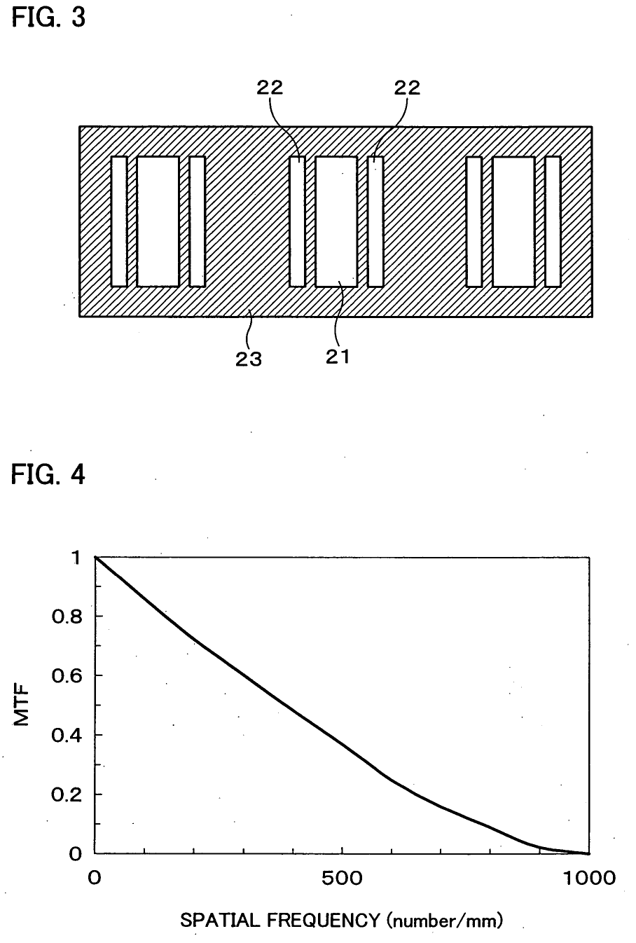

FIG. 3 is a frontal view illustrating a pattern formed on the mask 67 of the fabrication device according to the present embodiment for fabricating a crystallized semiconductor thin film. In the present embodiment, on the mask 67, sub beam forming patterns 22 are formed close to both sides of a main beam forming pattern 21. Concretely, the sub beam forming patterns 22 are formed so as to adjoin the main beam forming pattern 21. As a result, a laser light launched by the laser oscillator 61 can be irradiated as the sub energy beam adjoining the main energy beam to the semiconductor thin film 5. Note that in the present embodiment, a main beam forming pattern 21 and two sub beam forming patterns 22 are combined as a pattern group, and one or more pattern groups can be formed. In FIG. 3, three pattern groups are formed.

Here, a relation between the main beam forming pattern 21 and the sub beam forming pattern 22 is explained in terms of a size.

The width of the main beam forming pattern 21 may be about (the twice of lateral growth length/the magnification of the imaging lens). Concretely, it is possible to set the width, for example, between about 12 and 60 μm. In the present embodiment, the width of the main beam forming pattern 21 is set as 24 μm.

The width of the sub beam forming pattern 22 is set according to resolution of the imaging lens. The width of the sub beam forming pattern 22 is set to be equal to or smaller than (the resolution of the imaging lens/the magnification of the imaging lens), so that energy density of a beam that penetrates the sub beam forming pattern 22 can be made sufficiently smaller than energy per unit area (hereinafter referred to as energy density) of the main beam 6. By using this property, in the present embodiment, the width of the sub beam forming pattern 22 is set so that energy density of the main beam 6 can fuse the entire region in a thickness direction of the semiconductor thin film and energy density of the sub beam 7 cannot fuse the semiconductor thin film 5. Namely, the energy density of the main beam 6 is set so as to fuse the entire region in a thickness direction (a direction of lamination laminated on a substrate) of the semiconductor thin film 5 when it is irradiated to the semiconductor thin film 5. On the other hand, the sub beam 7 cannot fuse the semiconductor thin film 5 by itself when it is irradiated to the semiconductor thin film. Namely, the energy density of the sub beam 7 is set so as to be smaller than that of the main beam 6 and smaller than an energy threshold at which the semiconductor thin film 5 fuses. In other words, the sub beam 7 may have energy density that cannot crystallize the semiconductor thin film 5 but can warm the semiconductor thin film 5.

Concretely, for example, when the number of aperture (=NA) of the imaging lens is 0.15 and the wavelength of the light is λ (=0.308 μm), resolution R is approximately R=λ/NA=0.308/0.15=2.1 μm. Further, the magnification of the imaging lens is ¼, so that the width of the sub beam forming pattern 22 is 4.0 μm, being equal to or smaller than (resolution R/the magnification of the imaging lens).

FIG. 4 is a graph illustrating MTF (Modulus Transfer Function) of the imaging lens 68 used in the fabrication device according to the present embodiment for fabricating a crystallized semiconductor thin film. As explained above, the magnification of the imaging lens is ¼, so that the width of the main beam 6 that penetrates the imaging lens 68 and is irradiated to the semiconductor thin film 5 is 6 μm. Therefore, spatial frequency at this time becomes 1/(0.006×2)=83 (number/mm), and it is set so that MTF=0.89 because of a relation between the spatial frequency and MTF shown in FIG. 4. Further, just like the above, the width of the sub beam 7 irradiated to the semiconductor thin film 5 is 1 μm, so that spatial frequency becomes 1/(0.001×2)=500 (number/mm), and it is set so that MTF=0.37 at this time. The MTF represents contrast of images, so that controlling the slit width of mask patterns also controls energy density of the beam irradiated to the semiconductor thin film. Thus, it is possible to realize a condition under which the main beam 6 fuses the semiconductor thin film 5 over the whole area in a thickness direction and the sub beam 7 does not fuse but warm the semiconductor thin film 5.

A distance between the main beam 6 and the sub beam 7 should be set by the same reason as the reason for which the width of the sub beam 7 is set, and in the present embodiment, the distance is set as 1.0 μm.

A mask pattern (width of the main or sub beam forming pattern) is determined according to the size of the beam on the semiconductor thin film and the magnification of the imaging lens. In the present embodiment, an imaging lens of ¼ in magnification is used, and therefore a mask pattern is 4 times as large as the size of the beam irradiated to the semiconductor thin film 5.

The crystallized semiconductor thin film is fabricated by the fabrication device with the above arrangement. Concretely, in the present embodiment, the crystallized semiconductor thin film is fabricated by irradiating the sub beam 7 so that the sub beam 7 adjoins the main beam 6 in irradiation of a laser light to the semiconductor thin film 5.

Here, the following explains temperature distribution in a case when a laser light is irradiated to the semiconductor thin film 5 as shown in the above.

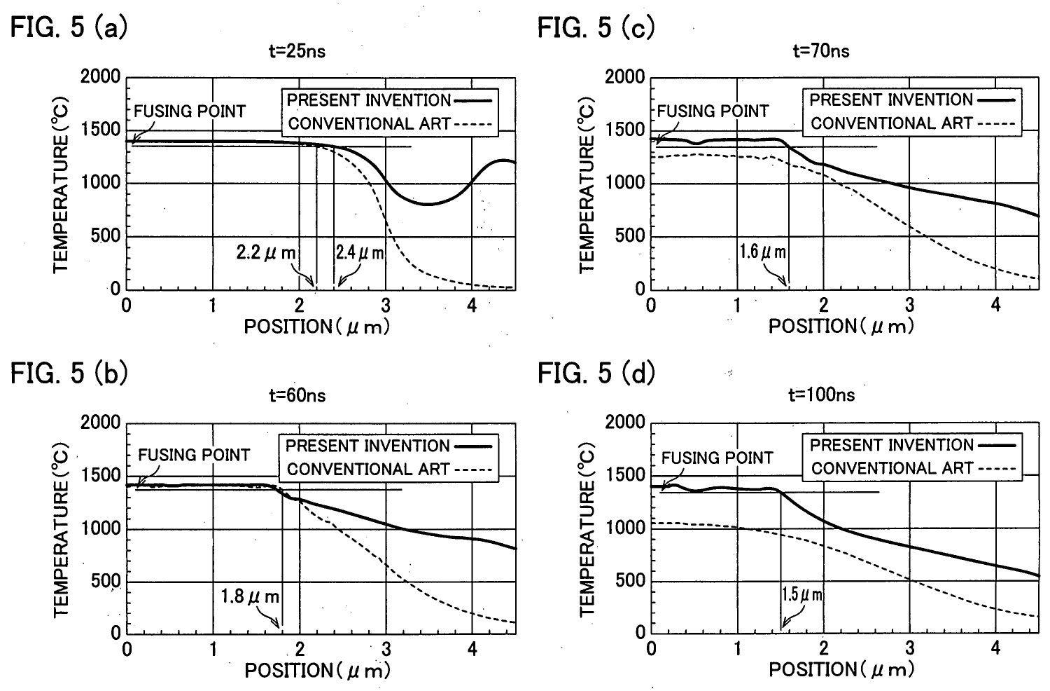

FIG. 5 is a graph illustrating a result of calculation of unsteady thermal conduction by a finite element method. FIG. 5(a) through FIG. 5(d) are temperature profiles in a chronological order. Horizontal axis of each graph shows a position (distance) from the center of a laser-irradiated region and vertical axis shows temperature of a bottom side of the semiconductor thin film. In FIG. 5(a) through FIG. 5(d), a fusing point means a fusing point of amorphous silicon that is a material constituting the semiconductor thin film 5 used in the present embodiment. FIG. 5(a) is a graph showing a temperature profile indicative of a condition in 25 ns after irradiation has been started, 25 ns being a time when temperature of the whole semiconductor thin film rises the highest. At this time, in usual process of crystallization (usual example), a semiconductor thin film is fused as far as a point 2.2 μm away from the center of a laser-irradiated region. On the other hand, in a process of crystallization of the present embodiment, a semiconductor thin film is fused as far as a point 2.4 μm away from the center of a laser-irradiated region. Namely, in the usual example, a region where the semiconductor thin film is completely fused in a thickness direction is a region of 4.4 μm in width, but in the process of the present embodiment, it is 4.8 μm. Note that the usual example explained here is an arrangement in which only the main beam 6 is irradiated to the semiconductor thin film, and concretely, an arrangement in which only the main beam 6 is irradiated so that energy density of the main beam 6 is the same as energy density of the main beam 6 according to the present embodiment.

FIG. 5(b) through FIG. 5(d) are graphs showing temperature profiles of the process of crystallization (solidification) of the semiconductor thin film, and each graph shows a temperature profile indicative of a condition in 60 ns after irradiation has been started, a condition in 70 ns after irradiation has been started, and a condition in 100 ns after irradiation has been started.

The method according to the present embodiment for fabricating a crystallized semiconductor thin film is referred to as a lateral growth process. This lateral growth process is explained in the following. When a laser light is irradiated to a semiconductor thin film, the semiconductor thin film fuses, numerous crystal nuclei are formed on boundaries between a region where the semiconductor thin film is completely fused in a thickness direction and a region where it is not fused, and crystals grow toward the center of a laser-irradiated region. Further, in the center of the laser-irradiated region, heat moves in a substrate direction, thereby forming minute crystals. Further, as shown in FIG. 5(a) through FIG. 5(d), graphs of temperature profiles show a condition under which the semiconductor thin film is crystallized, so that it is possible to confirm a condition of such lateral growth. Note that in explanation of the present embodiment, a thickness direction means a direction toward a thickness of the semiconductor thin film laminated on the substrate, and a lateral growth direction means an in-plane direction of the substrate.

First, based on the graphs of the temperature profiles shown in FIG. 5(a) through FIG. 5(d), crystallization of the usual example is explained. In the case of the usual example, the graph of the temperature profile shown in FIG. 5(b), namely, a condition at a time of 60 ns is such that: in a region ranging from a point 0 indicative of the center of a laser-irradiated region to a point positioned away by 1.81 μm, temperature of the semiconductor thin film is higher than a fusing point of a material constituting the semiconductor thin film. Namely, in a region ranging from a point 0 indicative of the center of the laser-irradiated region to a point positioned away by 1.8 μm, the semiconductor thin film is fused. Further, at a time of 25 ns shown in FIG. 5(a), the semiconductor thin film is fused in a region ranging from the point 0 to a point positioned away by 2.2 μm. Therefore, in a time from (i) 25 ns after irradiation of the laser light to the semiconductor thin film has been started to (ii) 60 ns after the irradiation has been started, the fused semiconductor thin film is crystallized in a region ranging from (a) a point positioned away by 2.2 μm from the point 0 indicative of the center of the laser-irradiated region to (b) a point positioned away by 1.8 μm from the point 0, i.e. in such a region that 2.2−1.8=0.4 μm. Namely, in the region of 0.4 μm, crystals are formed. However, as shown in FIG. 5(b) and FIG. 5(c), in a very short time of 10 ns that is between (i) 60 ns after the irradiation has been started and (ii) 70 ns after the irradiation has been started, the whole area receiving the laser light becomes under a fusing point.

At this time, as mentioned above, in the center of the laser-irradiated region, heat does not move in a lateral growth direction, but in a normal direction of the substrate, so that crystals do not make lateral growth, but become minute crystals. Namely, in the 10 ns, the fused semiconductor thin film gets rapidly cooled down and becomes under a fusing point. Therefore, in the region of the fused semiconductor thin film, before crystals generated in the region of 0.4 μm grow, a lot of minute crystals are generated. As a result, in the usual example, a crystallized semiconductor thin film having large crystals cannot be obtained.

Concretely, in the usual example, as apparent from the graphs of the temperature profiles shown in FIG. 5(b) and FIG. 5(c), crystals make lateral growth from the edge of the fused region (in the present usual example, a point positioned away by 2.2 μm from the center of the laser-irradiated region) in a central direction so as to range from 0.4 to 0.6 μm in length, and crystals become minute in the region from the center of the laser-irradiated region to a point positioned away therefrom by 1.6 through 1.8 μm. Note that even if a slit width is more broadened, the region of minute crystals at the center of the laser-irradiated region becomes larger accordingly, but the length of lateral growth hardly changes.

The present embodiment is fully explained in the following. In the method according to the present embodiment for fabricating a crystallized semiconductor thin film, from the time of 25 ns after irradiation of the laser light to the semiconductor thin film has been started through the time of 60 ns after the irradiation has been started, change of the fused region of the semiconductor thin film is the same as the usual example of the above explanation. Therefore, from the time of 25 ns after irradiation of the laser light to the semiconductor thin film has been started through the time of 60 ns after the irradiation has been started, produced crystals are about 2.4−1.8=0.6 μm. Next, in 10 ns that is a time from (i) 60 ns after the irradiation has been started through (ii) 70 ns after the irradiation has been started, as shown in FIG. 5(b) and FIG. 5(c), a fused region of the semiconductor thin film transits (moves) from (a) a point positioned away by 1.8 μm from the center of the laser-irradiated region to (b) a point positioned away by 1.6 μm from the center. Namely, in the 10 ns, only a region of 1.8−1.6=0.2 μm newly becomes under a fusing point of the semiconductor thin film. Therefore, in this region, crystallization of the semiconductor thin film occurs. In this case, in the region of the 0.2 μm, instead of new generation of minute crystals, crystal growth occurs so that already grown crystals positioned away by 1.8 μm from the center of the laser-irradiated region serve as seed crystals. The reason is that, unlike the usual example, seed crystals are positioned near to a newly crystallized region and therefore growth of seed crystals occurs so that the already existing seed crystals are centered, instead of new generation of minute crystals.

Further, in 30 ns that is a time from (i) 70 ns after the irradiation of the laser light has been started through (ii) 100 ns after the irradiation of the laser light has been started, the region of the fused semiconductor thin film transits (moves), as shown in FIG. 5(c) and FIG. 5(d), from (a) a point positioned away by 1.6 μm from the center of the laser-irradiated region to (b) a point positioned away by 1.5 μm from the center. In a region of 1.6−1.5=0.1 μm that has become under a fusing point in this 30 ns, already produced crystals grow by the above reason.

Therefore, at the time of 100 ns after the irradiation of the laser light has been started, as shown in FIG. 5(d), a point positioned away by 1.5 μm from the laser-irradiated region becomes under a fusing point, and crystallization of this point begins. At the time, the length of a crystal having made lateral growth is, according to FIG. 5(a) and FIG. 5(d), 2.4−1.5=0.9 μm. Therefore, in the method according to the present embodiment for fabricating a crystallized semiconductor thin film, the length of a growing crystal in a lateral growth direction increases by 50 through 125% compared with the usual example. In other words, the method according to the present embodiment for fabricating a crystallized semiconductor thin film can increase the length of a crystal growing in a lateral growth direction by 1.5 through 2.25 times compared with the usual example.

As described above, a result of calculation of unsteady thermal conduction by a finite element method shows that: the method according to the present embodiment for fabricating a crystallized thin film enables the length of a crystal in a lateral growth direction to be increased compared with the usual.

In order to verify the effects explained in the above, a crystallization experiment was performed by irradiating a laser light to the semiconductor thin film. A result of the experiment shows that an effect almost the same as the above explanation was obtained. Namely, with the method according to the present embodiment for fabricating a crystallized semiconductor thin film, the sub beam 7 is irradiated so as to adjoin the main beam 6, so that temperature change of the semiconductor thin film can be gradual. As a result, a lateral growth length of a crystal of the crystallized semiconductor thin film can be enlarged.

As shown above, the method according to the present embodiment for fabricating a crystallized semiconductor thin film is such that: focusing attention on the fact that a place near to a fusing point of the fused semiconductor thin film 5 moves with time in terms of temperature distribution of the fused semiconductor thin film 5, the outside of the place near to a fusing point (in the present embodiment, a place positioned away by 4 through 5 μm from the center of the main beam) is heated by the sub beam 7, so that movement of a place at a fusing point on the semiconductor thin film 5 becomes slowly. The fused semiconductor thin film 5 gets crystallized when its temperature gets under a fusing point. At the time, speed of crystallization is made slow (a region of crystallization is made narrow), so that it is possible to enlarge a growing crystal, concretely, the distance in a lateral growth direction of a crystal. In the method according to the present embodiment for fabricating a crystallized semiconductor thin film, by heating the outside of a region on the verge of crystallization in the semiconductor thin film 5 fused by the main beam 6, a region crystallized at once is narrowed. As a result, a ratio of crystal growth with already existing seeds centered is higher than a ratio of generation of minute crystals unlike the usual. Therefore, it is possible to fabricate a crystallized semiconductor thin film whose crystals are larger than those of the usual.

Note that the above description explained an arrangement of irradiating the main beam 6 and the sub beam 7 to the semiconductor thin film 5 so that they adjoin each other with a certain distance between them. However, in the method according to the present embodiment for fabricating a crystallized semiconductor thin film, when a light course from a laser oscillator to a substrate is diverged, or when two laser irradiating means are used, it may be so arranged that the main beam 6 and the sub beam 7 are irradiated to the semiconductor thin film 5 so that the two beams partially overlap each other. However, the main beam 6 and the sub beam 7 do not overlap entirely. Further, as for a distance between the main beam 6 and the sub beam 7 irradiated to the semiconductor thin film 5, when a width of the main beam 6 irradiated to the semiconductor thin film 5 ranges from 3 to 15 μm, for example, it is preferable that the distance ranges from 1 to 8 μm, and it is more preferable that the distance ranges from 2 to 6 μm. The distance is set to be within the above range, so that it is possible to further enlarge a size of a growing crystal (grain size of a crystal).

Note that in the above explanation, an arrangement to use a laser light as an energy beam is explained, but an energy beam of the present invention is not limited to the above, and an electron beam may be used for example.

### Second Embodiment

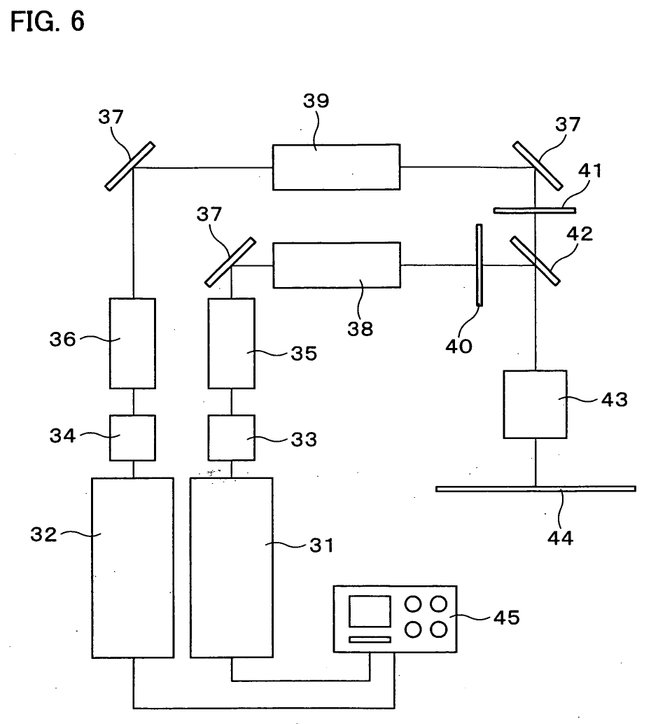

An explanation of another embodiment of the present invention, with reference to FIG. 6 through FIG. 8, is as follows.

In the present embodiment, it is possible to further increase a lateral growth length by adjusting timings at which a main beam 6 and a sub beam 7 are irradiated with two laser irradiating devices.

Concretely, a fabrication device according to the present embodiment for fabricating a crystallized semiconductor thin film includes: a first beam irradiating section for performing pulse irradiation of the main energy beam 6; a first mask for forming a pattern of the main energy beam 6 irradiated by the first beam irradiating section; a second beam irradiating section for irradiating the sub energy beam 7 whose energy per unit area is smaller than that of the main energy beam 6 and lower than an energy threshold at which a semiconductor thin film fuses; a second mask for forming a pattern of the sub energy beam 7 irradiated by the second beam irradiating section; an imaging lens for imaging patterns respectively formed by the first mask and second mask, on the semiconductor thin film, the first mask and second mask forming patterns by which the sub energy beam 7 is irradiated to the semiconductor thin film so as to adjoin the main energy beam 6. Note that, for convenience of explanation, members having the same functions as those already described in the first embodiment are given the same reference numerals and explanations thereof are omitted here. Concretely, in the present embodiment, the same semiconductor thin film as in the first embodiment is used. Other layers (such as a substrate) are arranged in the same manner as in the first embodiment.

In the fabrication device according to the present embodiment for fabricating a crystallized semiconductor thin film, as shown in FIG. 6, optical parts constituting a first laser course that extends from a first laser oscillator (a first beam irradiating section) 31 to a substrate 44 including a semiconductor thin film 5 and a second laser course that extends from a second laser oscillator (a second beam irradiating section) 32 to the substrate 44 are arranged in the same manner as in the first embodiment. Namely, optical parts such as variable attenuators (33, 34), beam forming elements (35, 36), mask surface uniformly illuminating elements (38, 39) and masks (40, 41; controlling means), are respectively arranged in the same manner as the variable attenuator 63, the beam forming element 64, the mask surface uniformly illuminating element 65, the field lens 66 and the mask 67, of the fabrication device according to the first embodiment, as shown in FIG. 2. Further, the fabrication device according to the present embodiment includes, besides the above parts, a beam splitter 42 and a pulse generator (controlling means) 45. Further, an energy irradiating means is constituted of optical parts (including the beam splitter 42 and an imaging lens 43) making up the first laser light course and second laser light course.

The main beam 6 is formed in the first laser light course and the sub beam 7 is formed in the second laser light course. Further, the first laser light course and the second laser light course are combined by the beam splitter 42. Further, the imaging lens 43 unites two laser lights respectively irradiated by the first laser light course and the second laser light course, and irradiates thus united laser lights to the semiconductor thin film 5.

The pulse generator 45 is used to control an oscillation timing of the laser oscillator. Each of the laser oscillators 31 and 32 is arranged so as to irradiate a pulse laser without delay when controlling pulse is inputted by the pulse generator 45. Further, the pulse generator 45 can control irradiation timings of pulse lasers irradiated by the first laser oscillator 31 and the second laser oscillator 32.

Further, in the present embodiment, adjustment of energy (energy density) of a laser light irradiated by each of laser oscillators 31 and 32 can be performed separately. Concretely, on the basis of the first variable attenuator 33 and the second variable attenuator 34, or on the basis of shapes of patterns formed in the first mask 40 and the second mask 41, energy density of each laser light can be adjusted.

Wavelengths of laser lights (pulse lasers) irradiated by laser oscillators 31 and 32 are both set as 308 nm.

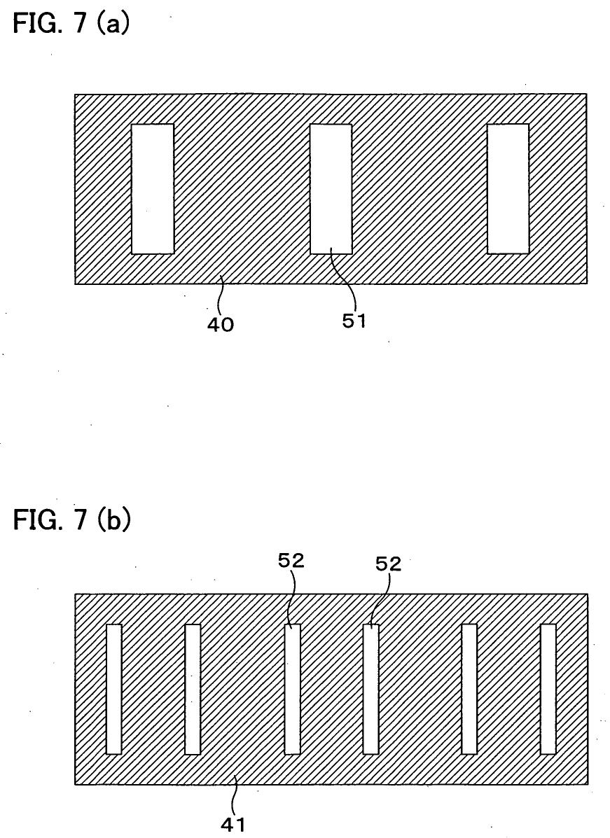

The first mask 40 and the second mask 41 are used to form the main beam 6 and the sub beam 7 respectively. FIG. 7 is a frontal view showing masks used in the fabrication device according to the present embodiment for fabricating a crystallized semiconductor thin film, concretely, showing structures of patterns formed in the masks. In the first mask 40 forming the main beam 6, as shown in FIG. 7(a), three slits each of which has a predetermined width are formed. In the second mask 41 forming the sub beam 7, as shown in FIG. 7(b), six slits each of which has a width narrower than that of the main beam 6 are formed. Note that in this figure, three sets of mask patterns of the main beam 6 and the sub beam 7 are provided. Therefore, a mask pattern corresponding to a set of a main beam 6 and a sub beam 7 are a main beam forming pattern 51 and two sub beam forming patterns 52 adjoining the pattern 51 with certain distances between them. In the present embodiment, sizes of patterns formed in masks 40 and 41 are set to be the same as in the first embodiment.

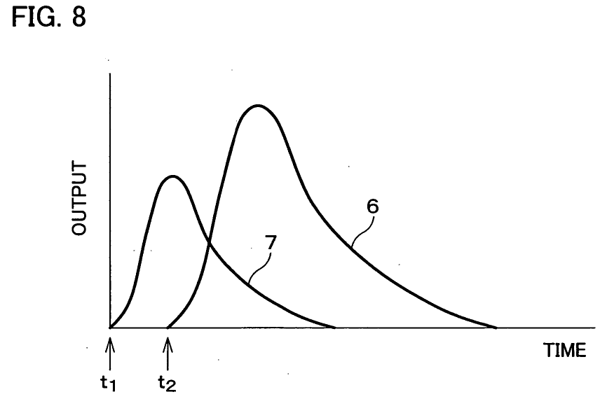

Energy density of a laser light irradiated to the semiconductor thin film 5 is, just like the first embodiment, adjusted by a size of a mask pattern, but it can be adjusted more minutely by respective laser oscillators 31 and 32, or by respective variable attenuators 33 and 34. A timing for irradiating a laser light (pulse beam) should be set so that a warming effect by the sub beam 7 is realized. Namely, the main beam 6 is irradiated while the sub beam 7 keeps the semiconductor thin film 5 warm. Concretely, as shown in FIG. 8, in time-varying curve of the sub beam 7, temperature of a thin film becomes almost a maximum at a time t2 when output of the sub beam 7 becomes a maximum, and therefore the main beam 6 is irradiated at this time.

With an arrangement of the present embodiment, the same simulation result as that of the first embodiment can be obtained. Further, a crystallization experiment of irradiating a laser to the semiconductor thin film 5 brought almost the same effect as the above simulation result.

In the present embodiment, the sub beam 7 is irradiated so as to adjoin the main beam 6. As for this, there are several processes such as (1) a process in which the main beam 6 and the sub beam 7 are irradiated synchronously; (2) a process in which the sub beam 7 is irradiated beforehand, and while the sub beam 7 is irradiated, the main beam 6 is irradiated so as to adjoin the sub beam 7; and (3) a process in which the main beam 6 is irradiated beforehand, and while the main beam 6 is irradiated, the sub beam 7 is irradiated so as to adjoin the main beam 6. Out of the above processes, the process (2) is more preferable in that it is possible to heat the semiconductor thin film 5 beforehand at a level where the semiconductor thin film 5 does not fuse. Especially, it is preferable to begin irradiation of the main beam 6 at a timing when energy density of the sub beam 7 on the surface of the semiconductor thin film 5 becomes substantially a maximum, most preferably just at a maximum.

By heating the semiconductor thin film 5 beforehand at a level where it does not fuse, the semiconductor thin film 5 can be fused soon and besides circumference of the fused region of the semiconductor thin film 5 can be kept warm, so that the fused semiconductor thin film 5 can be crystallized slowly. As a result, a size of a crystal of the crystallized semiconductor thin film (length of a needle-like crystal) can be made larger than usual.

### Third Embodiment

An explanation of another embodiment of the present invention is as follows. Note that, for convenience of explanation, members having the same functions as those already described in the first embodiment and second embodiment are given the same reference numerals and explanations thereof are omitted here.

The present embodiment is arranged so that: with two laser lights different from each other in terms of a wavelength, timings at which the main beam 6 and the sub beam 7 are irradiated are adjusted, thereby further increasing a lateral growth length. In the present embodiment, the same substrate as in the first embodiment is used.

Further, the fabrication device according to the present embodiment for fabricating a crystallized semiconductor thin film is basically the same as the second embodiment, but uses YAG laser of 532 nm in wavelength as the second laser oscillator 32 for forming the sub beam 7.

Further, a relation between the main beam 6 and the sub beam 7 in terms of a size is set in the same manner as in the second embodiment. Further, a timing to irradiate a laser light (pulse laser) and adjustment of energy density of each laser light are set in the same manner as in the second embodiment.

In the present embodiment, a wavelength of a laser forming the sub beam 7 is set as 532 nm. The reason is explained in the following. As a laser light forming the main beam 6, it is preferable to use a beam that has a low light-transmissivity and shallow depth of penetration against amorphous silicon constituting a semiconductor thin film 5 according to the present embodiment. On the other hand, as a laser light forming the sub beam 7, it is preferable to use a beam that has deep depth of penetration. Incidentally, when a light with intensity I₀ is launched to a material, intensity I at a place positioned away by a distance d from a light-receiving surface is represented as I=I₀ exp(−αd). Note that a is an absorption coefficient. Concretely, an absorption coefficient of a light whose wavelength is 308 nm is set as 1.2×106 cm⁻¹, and an absorption coefficient of a light whose wavelength is 532 nm is set as 2.0×105 cm⁻¹. According to the above equation, for example, in the case of calculating the value of d so that I/I₀<0.01, when a wavelength of the light is 308 nm, d is 40 nm, and when a wavelength of the light is 532 nm, d is 235 nm. In the present embodiment, a thickness of the semiconductor thin film 5 made of amorphous silicon is set as 50 nm, so that the light whose wavelength is 308 nm is almost absorbed in the semiconductor thin film 5, but the light whose wavelength is 532 nm almost penetrates the semiconductor thin film 5 and reaches lower layers such as a buffer layer 4 or a high temperature conductive insulating film 3. Therefore, the warming effect by the sub beam 7 can uniformly raise temperature of a deeper place by use of the laser light of 532 nm with a low absorption coefficient and deep depth of penetration at the semiconductor thin film 5. Because the sub beam 7 is irradiated for the purpose of preventing the fused semiconductor thin film 5 from changing its temperature rapidly near at a fusing point, it is preferable to irradiate a laser light whose wavelength is 532 nm as the sub beam 7 for the purpose of achieving the above object. Note that it is possible to use a laser light whose wavelength is 532 nm as a laser light forming the main beam 6, but the main beam 6 has high energy density and therefore, when it is irradiated so that depth of penetration becomes deep, it is necessary to be careful not to harm the lower layers of the semiconductor thin film, such as a glass substrate.

With an arrangement of the present embodiment, the same simulation result as that of the first embodiment can be obtained. When a crystallization experiment was performed by irradiating a laser light to the semiconductor thin film, almost the same effect as the above simulation effect was obtained. Namely, a crystallized semiconductor thin film whose distance in a lateral growth direction is longer than usual can be fabricated.

Note that in each embodiment, the shape of the light-penetrating part (a mask pattern) of the mask was explained as a rectangle, but the shape of the pattern is not limited to this, and a variety of slit shapes such as a mesh shape, a serrated shape, and a wave shape can be adopted.

Further, when two light courses are combined, a beam splitter is used in general, and in the case of two laser lights with the same wavelength, utilization efficiency of light becomes 50%. However, the present embodiment uses laser lights different from each other in terms of a wavelength, and therefore utilization efficiency of a beam can be 50% or more by optimal designing of a beam splitter.

Further, the method according to the present embodiment for fabricating a crystallized semiconductor thin film may be such that: a pulse energy beam in a minute slit shape is irradiated to the semiconductor thin film 5 and the semiconductor thin film 5 of the energy beam-irradiated region is fused and solidified over the whole area in a thickness direction so as to be crystallized, the semiconductor thin film 5 receiving the main beam 6 and the sub beam 7, having a smaller energy density than that of the main beam 6, which adjoins the main beam 6.

Further, the method according to the present invention for fabricating a crystallized semiconductor thin film may be such that: irradiation of the main beam 6 having higher energy density than that of the sub beam 7 is started after irradiation of the sub beam 7 to the semiconductor thin film 5 has been started with a timing at which energy density of the sub beam 7 on a surface of the semiconductor thin film 5 becomes a maximum.

Further, the method according to the present invention for fabricating a crystallized semiconductor thin film may be such that: energy beams are irradiated so that the main beam 6 and the sub beam 7 are different from each other in terms of a wavelength.

Further, the method according to the present invention for fabricating a crystallized semiconductor thin film may be such that: a high heat conductive insulator film 3 including at least one kind of chemical compounds selected from aluminum nitride, silicon nitride, aluminum oxide, magnesium oxide and cerium oxide, is formed as a lower layer of the semiconductor thin film 5.

Further, the fabrication device according to the present invention for fabricating a crystallized semiconductor thin film may include at least a laser light 61, a mask 67, and an imaging lens 68, and forms a mask image on the semiconductor thin film 5 so as to fuse and solidify the semiconductor thin film 5, the mask 67 including a pattern forming the sub beam 7 so that the pattern forming the sub beam 7 adjoins a pattern for forming the main beam 6.

Further, the fabrication device according to the present invention for fabricating a crystallized semiconductor thin film may include: a first laser oscillator 31 for performing pulse irradiation; a first mask 40; a second laser oscillator 32; a second mask 41; and an imaging lens 43, an image caused by the first mask 40 forming the main beam 6 and an image caused by the second mask 41 forming the second beam 7.

Further, the fabrication device according to the present invention for fabricating a crystallized semiconductor thin film may include: a controlling device that can irradiate a laser light from the first laser oscillator 31 and a laser light from the second laser oscillator 32 at timings different from each other; and a controlling device that can adjust energy density of the first laser oscillator 31 and energy density of the second laser oscillator 32 respectively.

Further, the fabrication device according to the present invention for fabricating a crystallized semiconductor thin film may be arranged so that the first laser oscillator 31 and the second laser oscillator 32 irradiate laser lights different from each other in terms of a wavelength.

As described above, the method according to the present invention for fabricating a crystallized semiconductor thin film includes the step of irradiating a main energy beam and a sub energy beam, whose energy per unit area is smaller than that of the main energy beam and lower than an energy threshold at which a semiconductor thin film fuses, to the semiconductor thin film formed on a substrate, so as to fuse the semiconductor thin film over a whole area in a thickness direction and crystallize the semiconductor thin film, wherein the sub energy beam is irradiated so as to adjoin the main energy beam.

With the arrangement, the sub energy beam is irradiated so as to adjoin the main energy beam. In general, a semiconductor thin film fused by pulse irradiation of a main energy beam is crystallized from circumference. At the time, in the present invention, to the circumference of this fused semiconductor thin film, a sub energy beam having smaller energy per unit area than the main energy beam is irradiated so as to adjoin the main energy beam. Further, the energy per unit area of the sub energy beam is set lower than an energy threshold at which the semiconductor thin film fuses. As a result, the fused semiconductor thin film is cooled down at slower speed than usual. Namely, the fused semiconductor thin film is crystallized gradually in crystallization. As a result, it is possible to increase a size of a crystal of the crystallized semiconductor thin film. Note that the main energy beam can fuse the semiconductor thin film. Namely, energy per unit area of the main energy beam is set higher than the energy threshold at which the semiconductor thin film fuses. Namely, with the arrangement, it is possible to control speed of crystallization (solidification) of the fused semiconductor thin film, in addition to precisely controlling a fused region of the semiconductor thin film.

Therefore, it is possible to change spatial temperature distribution of energy given to the semiconductor thin film and so the change of temperature in time and space in solidification (crystallization) becomes gradual. As a result, it becomes possible to increase the length (lateral growth length) of a needle-like crystal (a crystal made of material constituting a semiconductor thin film) that is formed by the lateral growth process.

Further, by irradiating the sub beam so that the sub beam adjoins the main beam, for example, it is possible to fabricate the crystallized semiconductor thin film in shorter time than a configuration in which multiple pulse lasers with different energies are irradiated to the same point multiple times and the semiconductor thin film is crystallized. As a result, fabrication efficiency of the crystallized semiconductor thin film is better than usual.

It is preferable to arrange the method according to the present invention for fabricating a crystallized semiconductor thin film so that irradiation of the main energy beam is started at a time when energy per unit area with which the sub energy beam is irradiated to a surface of the semiconductor thin film reaches a maximum.

With the arrangement, the main energy beam is irradiated at a time when irradiation of the sub energy beam has been started and its energy per unit area on the surface of the semiconductor thin film reaches a maximum.

As a result, optimization of spatial temperature distribution on the semiconductor thin film can be realized, thereby realizing optimization of temperature change in time and space in crystallization (in solidification) of the semiconductor thin film. As a result, it is possible to further increase the length of a needle-like crystal formed by the lateral growth process.

It is more preferable to arrange the method according to the present invention for fabricating a crystallized semiconductor thin film so that: the main energy beam and the sub energy beam are irradiated so as to be different from each other in terms of a wavelength.

With the arrangement, the main energy beam and the sub energy beam are irradiated to the semiconductor thin film so as to be different from each other in terms of a wavelength. Namely, by using two courses (light courses) of energy beams being different from each other, energy beams are irradiated to the semiconductor thin film. As a result, it is possible to increase utilization efficiency of an energy beam when two light courses are combined and irradiation to the semiconductor thin film is performed, so that the semiconductor thin film is fused more efficiently and then re-crystallization is possible.

It is more preferable to arrange the method according to the present invention for fabricating a crystallized semiconductor thin film so that the substrate has a thermal conductive insulator film formed between the substrate and the semiconductor thin film, and the thermal conductive insulator film is made of at least one material selected from aluminum nitride, silicon nitride, aluminum oxide, magnesium oxide, and cerium oxide.

With the arrangement, by providing the thermal conductive insulator film between the substrate and the semiconductor thin film, heat derived from the energy beam irradiated to the substrate can be quickly conducted in a horizontal direction of the semiconductor thin film, thereby promoting crystal growth (lateral growth) in a horizontal direction. Namely, a direction of crystallization can be set in a horizontal direction, so that the crystallized semiconductor thin film having larger crystals can be produced.

As described above, the fabrication device according to the present invention for fabricating a crystallized semiconductor thin film includes energy beam irradiating means for performing pulse irradiation so that a main energy beam and a sub energy beam, whose energy per unit area is smaller than that of the main energy beam and lower than an energy threshold at which a semiconductor thin film fuses, are irradiated to a semiconductor thin film formed on a substrate, wherein the energy beam irradiating means irradiates the sub energy beam so that the sub energy beam adjoins the main energy beam.

With the arrangement, the energy beam irradiating means irradiates the sub energy beam so that the sub energy beam adjoins the main energy beam. As a result, it is possible to irradiate the sub beam to the semiconductor thin film so that the sub beam adjoins the main beam, thereby providing a fabrication device for fabricating a crystallized semiconductor thin film having crystals whose lateral growth length is large.

It is more preferable to arrange the fabrication device according to the present invention for fabricating a crystallized semiconductor thin film so that the energy beam irradiating means includes (i) a mask for forming patterns of the main energy beam and the sub energy beam irradiated to the semiconductor thin film and (ii) an imaging lens for imaging said main energy beam and sub energy beam, which have penetrated said mask, on the semiconductor thin film, and the mask forms a pattern of the main energy beam and a pattern of the sub energy beam adjoining the pattern of the main energy beam.

With the arrangement, the sub energy beam is irradiated so as to adjoin the main energy beam by use of a shape of a mask pattern. Therefore, for example, by changing the shape of a mask pattern, shapes of the main energy beam and the sub energy beam can be changed easily, thereby easily optimizing an energy beam.

As described above, the fabrication device according to the present invention for fabricating a crystallized semiconductor thin film includes: a first beam irradiating section for performing pulse irradiation of a main energy beam; a first mask for forming a pattern of the main energy beam irradiated by the first beam irradiating section; a second beam irradiating section for irradiating a sub energy beam whose energy per unit area is smaller than that of the main energy beam and lower than an energy threshold at which a crystallized semiconductor thin film fuses; a second mask for forming a pattern of the sub energy beam irradiated by the second beam irradiating section; and an imaging lens for imaging patterns, respectively formed by the first mask and the second mask, on a semiconductor thin film, wherein the first mask and the second mask form patterns by which the sub energy beam is irradiated to the semiconductor thin film so as to adjoin the main energy beam.

With the arrangement, two energy beam irradiating means are used to irradiate the sub energy beam so that the sub energy beam adjoins the main energy beam. This enables the sub beam to be irradiated to the semiconductor thin film so as to adjoin the main beam, thereby providing the fabrication device for fabricating a crystallized semiconductor thin film having crystals whose lateral growth length is large. Further, by using two energy beam irradiating means, for example, it is possible to easily produce energy beams different from each other in terms of a wavelength.

It is more preferable to arrange the fabrication device according to the present invention for fabricating a crystallized semiconductor thin film so as to include controlling means for controlling a timing at which the main energy beam is irradiated by the first beam irradiating section and a timing at which the sub energy beam is irradiated by the second beam irradiating section; and adjusting means for respectively adjusting energy per unit area with which the main energy beam is irradiated by the first beam irradiating section and energy per unit area with which the sub energy beam is irradiated by the second beam irradiating section.

With the arrangement, adjustment of a timing at which an energy beam is irradiated and adjustment of energy are performed independently, so that the utilization efficiency of an energy beam can be increased.

It is more preferable to arrange the fabrication device according to the present invention for fabricating a crystallized semiconductor thin film so that the first beam irradiating section and the second beam irradiating section irradiate energy beams different from each other in terms of a wavelength.

With the arrangement, energy beams different from each other in terms of a wavelength are used to fabricate a crystallized semiconductor. As a result, for example, the utilization efficiency of energy beams such as a laser light can be increased, thereby further increasing the efficiency of re-crystallization.

Note that the above description explained an example in which pulse irradiation of energy beams (laser lights) is performed, but the energy beams may be successively irradiated to the substrate.

Note that concrete embodiments or examples shown in “BEST MODE FOR CARRYING OUT THE INVENTION” are first and foremost to clarify technical contents of the present invention, and the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The method according to the present invention for fabricating a crystallized semiconductor thin film and the fabrication device according to the present invention for fabricating a crystallized semiconductor thin film are favorably used as a fabrication method and a fabrication device for fabricating a crystallized semiconductor thin film by use of an energy beam, especially a laser light.

1. A method for fabricating a crystallized semiconductor thin film, comprising the step of irradiating a main energy beam and a sub energy beam, whose energy per unit area is smaller than that of the main energy beam and lower than an energy threshold at which a semiconductor thin film fuses, to the semiconductor thin film formed on a substrate, so as to fuse the semiconductor thin film over a whole area in a thickness direction and crystallize the semiconductor thin film, wherein
the sub energy beam is irradiated so as to adjoin the main energy beam.

2. The method as set forth in claim 1, wherein there is performed pulse irradiation of the main energy beam and/or the sub energy beam to the semiconductor thin film.

3. The method as set forth in claim 1, wherein irradiation of the main energy beam is started at a time when energy per unit area with which the sub energy beam is irradiated to a surface of the semiconductor thin film reaches a maximum.

4. The method as set forth in claim 1, wherein the main energy beam and the sub energy beam are irradiated so as to be different from each other in terms of a wavelength.

5. The method as set forth in claim 4, wherein a laser light whose wavelength is 532 nm is irradiated to the semiconductor thin film as the main energy beam and a laser light whose wavelength is 308 nm is irradiated to the semiconductor thin film as the sub energy beam.

6. The method as set forth in claim 1, wherein:
the substrate has a thermal conductive insulator film formed between the substrate and the semiconductor thin film, and
the thermal conductive insulator film is made of at least one material selected from aluminum nitride, silicon nitride, aluminum oxide, magnesium oxide, and cerium oxide.

7. A fabrication device for fabricating a crystallized semiconductor thin film, comprising energy beam irradiating means for performing pulse irradiation so that a main energy beam and a sub energy beam, whose energy per unit area is smaller than that of the main energy beam and lower than an energy threshold at which a semiconductor thin film fuses, are irradiated to a semiconductor thin film formed on a substrate, wherein
the energy beam irradiating means irradiates the sub energy beam so that the sub energy beam adjoins the main energy beam.

8. The fabrication device as set forth in claim 7, wherein:
the energy beam irradiating means includes (i) a mask for forming patterns of the main energy beam and the sub energy beam irradiated to the semiconductor thin film and (ii) an imaging lens for imaging said main energy beam and sub energy beam, which have penetrated said mask, on the semiconductor thin film, and
the mask forms a pattern of the main energy beam and a pattern of the sub energy beam adjoining the pattern of the main energy beam.

9. The fabrication device as set forth in claim 7, wherein the energy beam irradiating means performs pulse irradiation of the main energy beam and/or the sub energy beam.

10. The fabrication device as set forth in claim 7, wherein the energy beam irradiating means irradiates a laser light.

11. A fabrication device for fabricating a crystallized semiconductor thin film, comprising:
a first beam irradiating section for irradiating a main energy beam;
a first mask for forming a pattern of the main energy beam irradiated by the first beam irradiating section;
a second beam irradiating section for irradiating a sub energy beam whose energy per unit area is smaller than that of the main energy beam and lower than an energy threshold at which a crystallized semiconductor thin film fuses;
a second mask for forming a pattern of the sub energy beam irradiated by the second beam irradiating section; and
an imaging lens for imaging patterns, respectively formed by the first mask and the second mask, on a semiconductor thin film, wherein
the first mask and the second mask form patterns by which the sub energy beam is irradiated to the semiconductor thin film so as to adjoin the main energy beam.

12. The fabrication device as set forth in claim 11, comprising:
controlling means for controlling a timing at which the main energy beam is irradiated by the first beam irradiating section and a timing at which the sub energy beam is irradiated by the second beam irradiating section; and
adjusting means for respectively adjusting energy per unit area with which the main energy beam is irradiated by the first beam irradiating section and energy per unit area with which the sub energy beam is irradiated by the second beam irradiating section.

13. The fabrication device as set forth in claim 11, wherein the first beam irradiating section and the second beam irradiating section irradiate energy beams different from each other in terms of a wavelength.

14. The fabrication device as set forth in claim 11, wherein the first beam irradiating section and/or the second beam irradiating section perform pulse irradiation of energy beams.
